(19) United States
(12) Patent Application Publication
(10) Pub. No.: US 2011/0170831 A1
(43) Pub. Date: Jul. 14, 2011

(54) OPTICAL MODULE AND MANUFACTURING METHOD OF THE MODULE

(75) Inventor: Mitsuaki TAMURA, Yokohama-shi (JP)

(73) Assignee: SUMITOMO ELECTRIC INDUSTRIES, LTD., Osaka-shi (JP)

(21) Appl. No.: 12/976,331

(22) Filed: Dec. 22, 2010

(30) Foreign Application Priority Data
Jan. 8, 2010 (JP) 2010-003074

(51) Int. Cl. G02B 6/36; H05K 3/30

(52) U.S. Cl. 385/88; 29/832

(57) ABSTRACT

An optical module 1 comprises a base 2 and an opto-electric device 3 including a first surface 3A having an active layer 31 provided thereon and a second surface 3B lying opposite the first surface 3A and facing the base 2. Bumps 3a are provided on the second surface 3B and the opto-electric device 3 is fixed to the base 2 through the bumps 3a. Thus, the distance between the opto-electric device 3 and the optical part can be decreased, since it is unnecessary to provide a transparent member and a bump for supporting the opto-electric device between the active layer of the opto-electric device and an external input/output member for an optical signal. The opto-electric device can be fixed with high positional precision since its position does not shift while being fixed to the base 2.

### BACKGROUND OF THE INVENTION

1. Field of the Invention

The present invention relates to an optical module and manufacturing method thereof.

2. Description of the Background Art

In recent years, the throughput of a supercomputer as well as the volume and speed of communication networks has increased. Therefore, the limit of transmission speed in an electrical connection between equipment has been a problem to be solved. To solve such problem, much attention has been paid to optical inter-connection technologies. The inter-connection technologies are intended to improve transmission speed between equipment by using an opto-electric hybrid module (hereinafter called “optical module”) for connection between signal processors such as LSIs or connection between a signal processor and an external interface such as a router.

The optical module includes an opto-electric device having an active layer. When the opto-electric device is a light emitting device, the active layer generates light and emits an optical signal according to an electrical signal, and the optical signal passes through an optical part such as a lens in the optical module and is transmitted to an external element such as an optical fiber or the like. On the other hand, when the opto-electric device is a photodetector, an optical signal input from the optical fiber or the like passes through the optical part such as a lens in the optical module, and the optical signal is converted into an electrical signal at the active layer.

A known structure of the optical module is such that an opto-electric device is fixed to a base by applying an adhesive to a surface opposite to the surface having an active layer provided thereon. Although such fixing method is simple and convenient, the relative position of the opto-electric device with respect to the optical part tends to shift while the adhesive is being hardened, and consequently it has been impossible to form an optical path with high precision.

Also, in optical modules described in Japanese Patent Application Publication Nos. 2004-31508 and 2008-41770, a wiring layer is provided on a transparent base on which an optical part such as a lens is mounted, and an opto-electric device is flip chip mounted to the wiring layer through metal bumps. According to this mounting method, the opto-electric device and the transparent base can be positioned with high precision through the bumps. However, it is necessary to design the bumps to have some degree of size needed for keeping their mechanical strength since the bumps perform both functions of electrical connection and mechanical connection. Therefore, the bumps must be formed in a larger size than a bump that is intended to perform electrical connection only. Moreover, the opto-electric device and the optical part are inevitably distanced from each other by the thickness of the transparent base and the large bumps because the opto-electric device and the optical part are optically connected together through the transparent base.

### SUMMARY OF THE INVENTION

An object of the present invention is to provide an optical module in which an opto-electric device can be mounted on a base such that not only can an optical path be established with high precision in terms of relative position between the opto-electric device and an optical part, but also the distance between them can be decreased. Another object of the invention is to provide a method of manufacturing such optical module.

Thus, an optical module according to an embodiment of the invention comprises a base and an opto-electric device including a first surface having an active layer provided thereon and a second surface lying opposite the first surface and having first bumps or first pads provided thereon, wherein the opto-electric device is fixed to the base through the first bumps or the first pads.

Preferably, the first bumps or the first pads are formed of gold, and second pads or second bumps made of gold are provided on the base at the respective positions corresponding to the first bumps or first pads.

Also, preferably the optical module further comprises a transparent member covering the opto-electric device and fixed to the base such that the transparent member has an optical part at a position facing the active layer of the opto-electric device, and third bumps or third pads are provided at positions to contact the base so that the transparent member is fixed to the base through the third bumps or the third pads. In such case, the third bumps or the third pads may be formed of gold, and fourth pads or fourth bumps made of gold may be provided on the base at positions corresponding to the third bumps or third pads, respectively. The third bumps or the third pads may be made of a solder, and the transparent member may be made of a thermoplastic resin that enables the transparent member to exhibit an average transmissivity of 60% or more at a thickness of 2 mm for a wavelength in the range of 600 to 1000 nm when the transparent member has been kept at 200° C. for 10 minutes.

In addition, preferably the optical module further comprises a control circuit for controlling the opto-electric device provided on the base, wherein the control circuit and the opto-electric device are electrically connected by wire bonding.

Another embodiment of the present invention is a method of manufacturing an optical module, the method comprising: a step of forming first bumps or first pads on a second surface of an opto-electric device, the opto-electric device having a first surface on which an active layer is provided, the second surface being located opposite the first surface; and a step of fixing the opto-electric device to a base through the first bumps or the first pads.

The optical module manufacturing method of the present invention may further comprise: a step of providing, on the base, a control circuit for controlling the opto-electric device; and a step of electrically connecting the control circuit and the opto-electric device by wire bonding. Also, the optical module manufacturing method may further comprise a step of fixing a transparent member to the base such that an optical part provided therein covers the opto-electric device, wherein at the step of fixing the opto-electric device to the base, an alignment mark on the base may be used for positioning the opto-electric device and the base, and at the step of fixing the transparent member to the base, the transparent member may be arranged on the base with the alignment mark such that the optical part is located at a position facing the active layer.

According to the optical module of the present invention, it is unnecessary to provide a transparent member and a bump for supporting the opto-electric device between the active layer of the opto-electric device and an external input/output member for an optical signal. Therefore, it is possible to realize an optical module in which the distance between the opto-electric device and the optical part is short. Moreover, the opto-electric device can be fixed firmly to the base. Also, it is possible to fix the opto-electric device with high positional precision since the position of the opto-electric device does not tend to shift relative to the base during such fixing because the fixing can be accomplished in an extremely short time as compared with a case in which an adhesive is used for fixing.

### BRIEF DESCRIPTION OF THE DRAWINGS

FIG. 1 is a cross-sectional view of an optical module according to an embodiment of the present invention.

FIG. 2 is a top view of an optical module according to an embodiment of the present invention.

FIG. 3 is a plan view of an opto-electric device; that is, a view of a surface (second surface) opposite to an active layer.

FIG. 4 is a top view of a base.

FIG. 5 is a plan view in a state in which the opto-electric device is fixed to the base.

FIG. 6 is a plan view in a state in which a control circuit is arranged on the base.

FIG. 7 is a cross-sectional view of a modified embodiment of optical module according to the present invention.

### DETAILED DESCRIPTION OF THE INVENTION

Hereinafter, preferred embodiments of the present invention will be described in reference to the accompanying drawings. The drawings are provided for the purpose of explaining the embodiments and are not intended to limit the scope of the invention. In the drawings, an identical mark represents the same element so that the repetition of explanation may be omitted. The dimensional ratios in the drawings are not always exact.

### Whole Structure

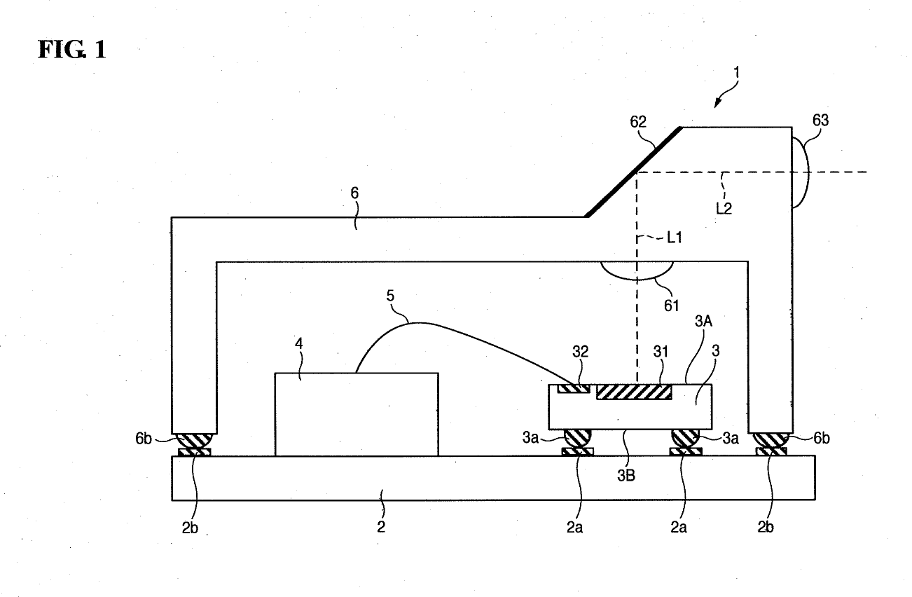

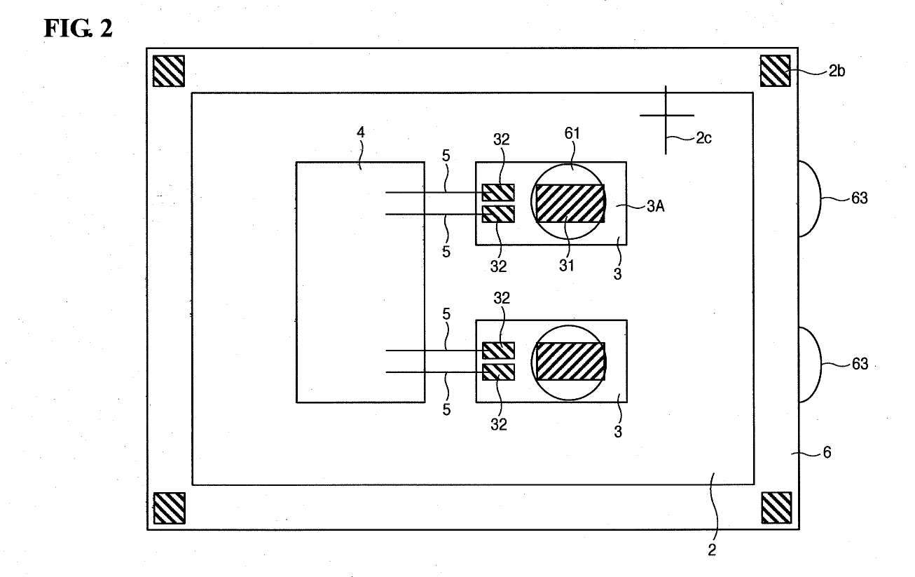

FIG. 1 is a cross-sectional view of an optical module according to an embodiment of the present invention, and FIG. 2 is a top view thereof. An optical module 1 comprises: a base 2; an opto-electric device 3 fixed on the base 2; a control circuit 4 fixed on the base 2; one pair of wires 5 that electrically connect the opto-electric device 3 and the control circuit 4; and a transparent member 6 that covers the opto-electric device 3, the control circuit 4, and the wires 5.

### Opto-Electric Device

An opto-electric device 3 has an active layer 31 provided on a first surface 3A and one pair of terminals 32 provided on the first surface 3A. When the opto-electric device 3 is a photodetector, the active layer 31 functions as a detector unit, and an electrical signal is transmitted to the control circuit 4 from the terminals 32 according to the received light signal. The photodetector 3 is a photodiode, for example. On the other hand, when the opto-electric device 3 is a light emitting device, the active layer 31 functions as a light emitting device, and the active layer 31 emits light toward the outside according to the electrical signal transmitted to the terminals 32 from the control circuit 4. The light emitting device is a vertical cavity surface emitting laser (VCSEL), for example. Although there are differences as mentioned above as to whether the opto-electric device is a light emitting device or a photodetector, the basic composition thereof is basically common while the input/output relationship between an optical signal and an electrical signal is reversed.

In the opto-electric device 3, metal bumps 3a (first bump) are provided on a second surface 3B that lies opposite the first surface on which the active layer 31 is provided. Metal pads 2a (second pad) are provided on the base 2 at positions which correspond to the metal bumps 3a and at which the opto-electric device 3 is fixed to the base 2. (The metal pads (first pad) may be provided on the side of the optical device 3, and the metal bump (second bump) may be provided on the side of the base.) These metal bumps 3a and metal pads 2a face each other, and are stuck together by a mounting method using ultrasonic welding or thermo-compression bonding so that the opto-electric device 3 is fixed to the base 2. The materials of the metal bumps 3a and the metal pads 2a are preferably gold or solder. Particularly, if both the metal bumps 3a and the metal pads 2a are made of gold and the opto-electric device 3 is fixed to the base 2 by the mounting method using ultrasonic welding, the opto-electric device 3 and the base 2 can be arranged with high precision in a short time.

It does not matter whether a single opto-electric device 3 is provided on the base 2 or a plurality of opto-electric devices are provided on the base 2. Also, it is possible to provide an optical module 1 in which a light emitting device and a photodetector are both provided as opto-electric devices 3 on the same base 2, thereby enabling mutual exchange of an optical signal and an electrical signal.

### Control Circuit

The control circuit 4 is fixed by bumps/pads or an adhesive onto the base 2. The control circuit 4 is electrically connected to the opto-electric device 3 through one pair of wires 5 one end of which is connected with the control circuit 4 and the other end is connected with one pair of terminals 32 of the opto-electric device 3. Through the wires 5, the control circuit 4 controls light emitting of the opto-electric device 3 according to a signal input from the outside when the opto-electric device 3 is a light emitting device, whereas the control circuit 4 receives an electrical signal from the opto-electric device 3 when the opto-electric device is a photodetector. Examples of control circuits 4 include an IC and a trans-impedance amplifier that amplifies the signal of a photodiode.

The wires 5 that connect the opto-electric device 3 and the control circuit 4 are wired by bonding. As will be described later, when arranging the control circuit 4 on the base 2, the transparent member 6 is still in an unarranged state, and hence the space above the base 2 is open. Therefore, it is easy to perform a wiring work by wire bonding between the opto-electric device 3 and the control circuit 4.

As described above, the opto-electric device 3 and the control circuit 4 are provided on the same single base 2, and therefore it is possible to provide the opto-electric device 3 and the control circuit 4 in a single module. Also, the opto-electric device 3 and the control circuit 4 can easily be connected by wire bonding.

### Transparent Member

The transparent member 6, which is arranged on the base 2 so as to cover the opto-electric device 3 and the control circuit 4, has a first lens 61, a reflecting plate 62, and a second lens 63. The first lens 61 is arranged at a position that faces the active layer 31 of the opto-electric device 3, and the reflecting plate 62 is arranged at an angle of 45 degrees relative to a phantom straight line L1 that links the active layer 31 and the first lens 61. The second lens 63 is arranged on a phantom straight line L2 that pass through the reflecting plate 62 and intersects the straight line L1 at a right angle. The transparent member 6 is formed by injection molding from a transparent resin integrally with the first lens 61, the reflecting plate 62, and the second lens 63.

The optical paths L1 and L2 are constituted by the first lens 61, the reflecting plate 62, and the second lens 63. The optical paths L1 and L2 connect the outside and the active layer 31 of the opto-electric device 3. Therefore, the first lens 61, the reflecting plate 62, and the second lens 63 must be positioned with high precision: if there is a discrepancy in the positioning, the connection loss between fibers for input/output of signals (not shown in the figure) increases, which in the worst case might cause a failure in transmission of optical signals.

When an opto-electric device 3 is a light emitting device, the active layer 31 generates light, and the light thus emitted is incident on the first lens 61, is reflected at the reflecting plate 62, thereby changing the direction by 90 degrees so as to be incident on the second lens 63, and finally is emitted outside the optical module 1. An optical fiber is arranged on an assumed line extending from the second lens 63, and an optical signal is transmitted to outside equipment via the optical fiber. In contrast, when the opto-electric device 3 is a photodetector, light is incident on the second lens 63 from an optical fiber of external equipment or the like, and the light is reflected at the reflecting plate 62, thereby changing the direction by 90 degrees so as to be incident on the first lens 61, and finally the light is incident on the active layer 31.

The first lens 61 and the second lens 63 are plano-convex lenses and may be arranged such that their focus coincides with the reflecting plate 62. With such a structure, when the opto-electric device 3 is a VCSEL, for example, the diffusion light emitted from the surface of the active layer 31 is condensed by first lens 61, is reflected at the reflecting plate 62, and becomes parallel light having less optical path differences through the second lens 63, which enables efficient optical transmission toward the outside. Also, for entering light into an optical fiber, it is possible to achieve efficient optical transmission by structuring so as to condense light again with the second lens 63 to enter into the optical fiber core at a focal point. In the above-mentioned example, the reflecting plate 62 is used so that light may be incident in the direction parallel to the first surface 3A of the opto-electric device 3; however, it is unnecessary to provide the reflecting plate 62 in the case where the optical fiber is arranged in perpendicular to the first surface 3A of the opto-electric device 3.

On the transparent member 6, metal bumps 6b (third bump) are provided at regions to touch the base 2. Metal pads 2b (fourth pad) are provided on the base 2 at positions to touch the transparent member 6 and corresponding to the metal bumps 6b. (The metal pads (third pad) may be provided on the side of transparent member 6 and the metal bumps (fourth bump) may be provided on the base side.) The metal bumps 6b and the metal pads 2b which face each other are stuck together respectively by mounting method using ultrasonic welding or thermo-compression bonding, or the like, and consequently the transparent member 6 can be fixed to the base 2 firmly with high positional precision. The materials of the metal bumps 6b and the metal pads 2b are preferably gold or solder.

Preferably, the metal bumps 6b are formed at regions which are different from the region where the optical part consisting of the first lens 61, the reflecting plate 62, and the second lens 63 is located. Such structure would prevent the occurrence of disadvantageous effects such as deformation which might otherwise be caused by heat spreading to the optical part during the time when the transparent member 6 is fixed to the base 2 by ultrasonic welding or thermo-compression bonding, or the like.

### Manufacturing Method

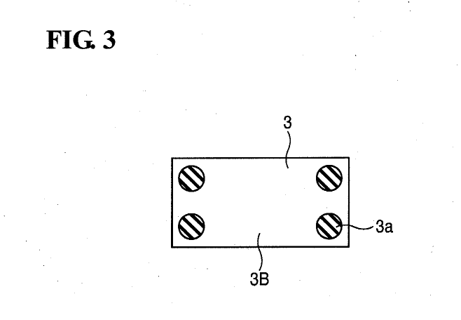

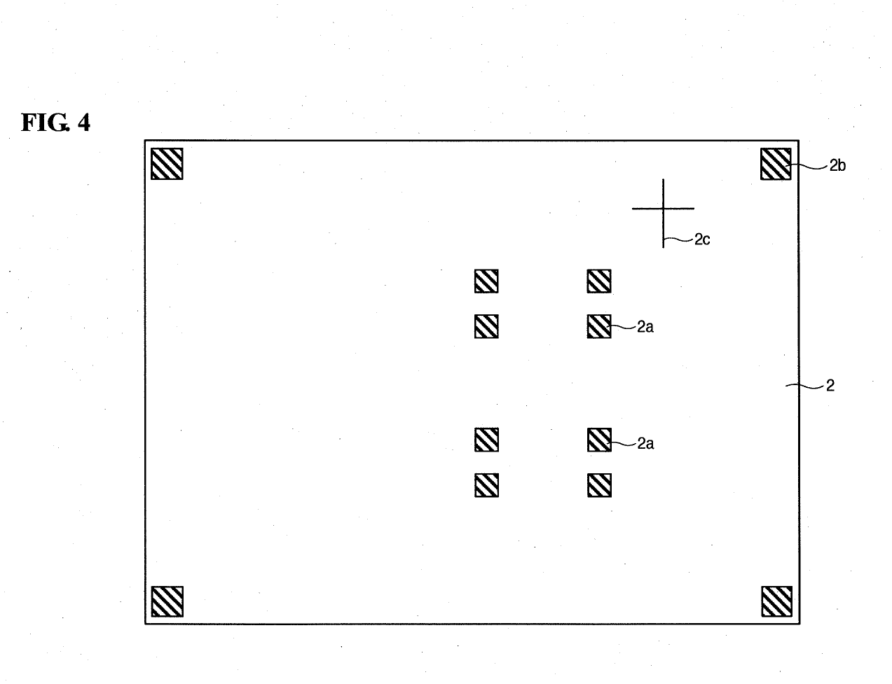

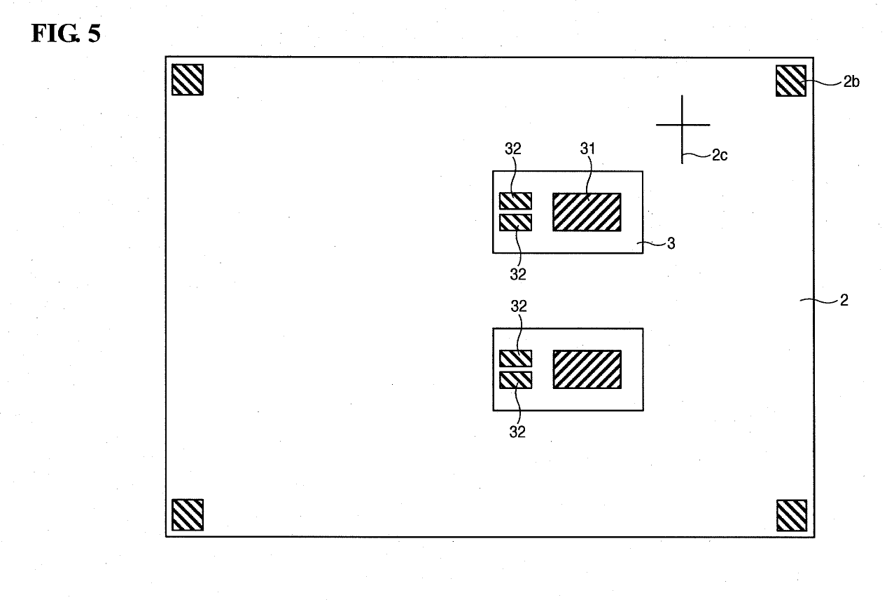

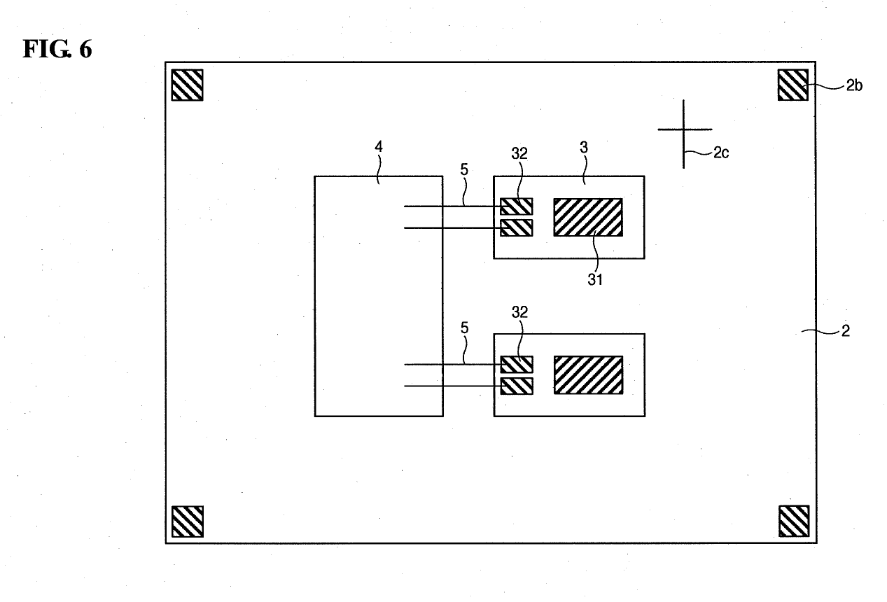

FIGS. 3 to 6 are drawings for explaining optical module manufacturing methods according to embodiments of the present invention: FIG. 3 is a plan view of the opto-electric device 3 seen from the face (second surface 3B) opposite the active layer 31; FIG. 4 is a top view of the base 2; FIG. 5 is a plan view in a state in which the opto-electric devices 3 are fixed to the base 2; and FIG. 6 is a plan view in a state in which the control circuit 4 is arranged on the base 2.

First, as shown in FIGS. 3 and 4, form metal pads 2a (second pad) and metal pads 2b (fourth pad) on the base 2, and also form metal bumps 3a (first bump) on the opto-electric device 3. For forming the metal pads 2a and the metal pads 2b, determine the positions of the metal pads 2a and the metal pads 2b by using an alignment mark provided on the base 2 as a normal position. The metal bumps 3a, the metal bumps 6b, the metal pads 2a, and the metal pads 2b may be provided at four corners as shown in FIG. 3 and FIG. 4, or otherwise, depending on the size of the opto-electric device 3 and the transparent member 6, at one location, or may be formed in an extending manner along two opposite sides or along four sides. The metal bumps (second bump, fourth bump) may be provided on the side of the base 2, and the metal pads (first pad) may be provided on the side of the opto-electric device 3.

Next, as shown in FIG. 5, using an alignment mark 2c on the base 2 as a normal position, arrange the opto-electric devices 3 on the base 2, connect the metal bumps 3a and the metal pads 2a, and fix the opto-electric device 3 to the basis 2. Subsequently, fix the control circuit 4 on the base 2 as shown in FIG. 6. It does not matter how the control circuit 4 is fixed to the base 2: it may be fixed by using a bump, an adhesive, or the like, since it does not constitute an optical path that requires high positional precision. In this embodiment, it is fixed with an adhesive. Once the control circuit 4 is fixed on the base 2, electrically connect the control circuit 4 and the terminals 32 of the opto-electric devices 3 by wire bonding using wires 5.

Subsequently, using the alignment mark 2c as a normal position, as shown in FIG. 2, place on the base 2 the transparent member 6 in which the metal bumps 6b (third bump) are formed. In such case, it is possible to arrange the transparent member 6 with high precision because the alignment mark 2c can be seen through the transparent member 6, the whole of which is transparent.

According to the above-mentioned steps, the positional relation between the transparent member 6 and the opto-electric device 3 can be confirmed by direct observation, and therefore while performing the arrangement of the transparent member 6, it is unnecessary to apply a current to the opto-electric device 3 to confirm whether the optical paths L1, L2 are established or not. In other words, since the positions of the opto-electric device 3 and the transparent member 6 are already determined by using the alignment mark 2c on the base 2 as the common standard position, it is possible to surely establish the optical paths L1, L2 by simply arranging the transparent member 6 at a pre-determined position relative to the base 2, whereby the active layer 31 of the opto-electric device 3, the first lens 61 of the transparent member 6, the reflecting plate 62, and the second lens 63 are arranged with high precision. According to such method, the relative position of the opto-electric device 3 and the transparent member 6 can be determined easily and with high precision as compared with the method of arranging the transparent member 6 while confirming whether an optical path is established or not while causing the active layer 31 of the opto-electric device 3 to emit light.

In the case where the metal bumps 6b are made of gold (Au) and the metal pads 2b are also made of gold (Au), the transparent member 6 can be fixed to the base 2 by a mounting method using ultrasonic welding. According to the mounting method using ultrasonic welding, the transparent member 6 and the base 2 can be joined without directly heating the transparent member 6 and the base 2, and it is possible to avoid any damage that the transparent member 6 might otherwise suffer from the heat. Since a resin is used for the transparent member 6, it is preferable that the metal bumps 6b and the metal pads 2b be made of gold and that the mounting method using ultrasonic welding be adopted, allowing the transparent member 6 to avoid being heated: otherwise the heat tends to transform the resin or the transmissivity of light might be degraded. According to this embodiment, the arrangement of the transparent member 6 relative to the base 2 can be achieved with high precision in a short time. Also, the transparent member 6 would not shift relative to the base 2 during the fixing process.

On the other hand, in the case where at least either the metal bumps 6b or the metal pads 2b are made of solder, the transparent member 6 can be fixed to the base 2 by thermo-compression bonding. According to the thermo-compression bonding, the cost can be reduced to a lower level by using a solder instead of gold as a material of the metal bumps 6b or the metal pads 2b. In such case, lest the transmissivity of the transparent member 6 might be degraded due to the heating during the soldering step, it is preferable to use a resin that will neither transform nor decrease the transmissivity even if the transparent member 6 is heated to a temperature above the melting point of the solder.

For the purpose of such a resin, it is preferable to use TERALINK™ (made by Sumitomo Electric Fine Polymer, Inc.) (see Japanese Patent Application Publication No. 2008-88303). TERALINK™ is one or more kinds of cross-linkable thermoplastic resins selected from the group consisting of transparent polyamide, cyclic polyolefin, fluororesin, polyester, acrylic, polycarbonate, and ionomer resin. Even when this resin is left in a thermostatic bath of 260° C. for one minute, it will not transform, or even if it transforms, the shape thereof can be maintained. Moreover, this resin will exhibit an average transmissivity of 60% or more at a thickness of 2 mm for a wavelength in the range of 600 to 1000 nm when it has been held for 10 minutes at 200° C. which is higher than the melting point (183° C.) of an eutectic solder. Accordingly, this resin is preferable because the transmissivity of light will not be degraded at a soldering step and the performance of the optical module will not decrease extremely even if a solder is used for at least either the metal bumps 6b or the metal pads 2b. For forming the metal bumps 6b and the metal pads 2b, it is possible to choose gold or solder in order to meet the desired specifications of an optical module to be made.

As to the metal bumps 3a and the metal pads 2a, it is also possible to form them using gold or solder as mentioned above so as to meet the aimed specifications of the optical module to be made. In the case where the opto-electric device 3 is a device which might easily be affected by heat, a high-precision optical module can be achieved by using gold for the metal bumps 3a and the metal pads 2a. In contrast, if the opto-electric device 3 is a device which might hardly be influenced by heat, it will be possible to provide an optical module at low cost using a solder for at least either of the metal bumps 3a or the metal pads 2a.

### Modified Example

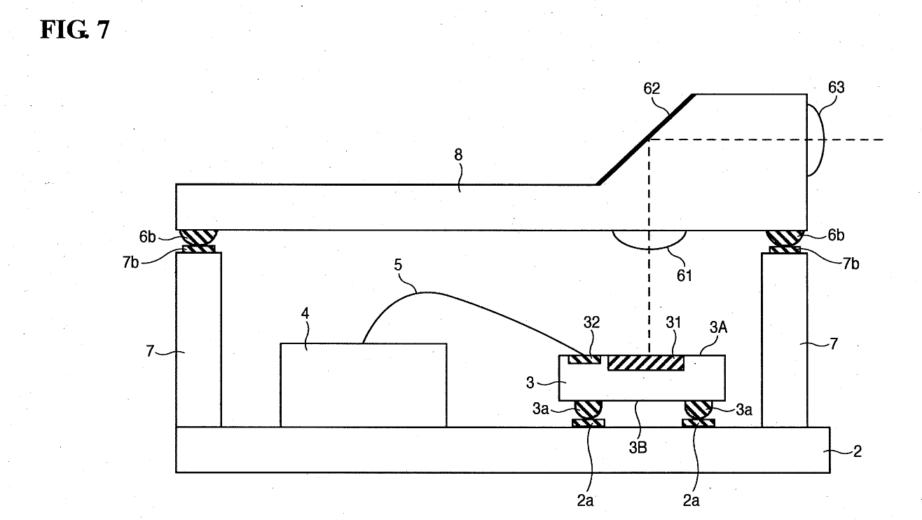

In the first embodiment, the legs of the transparent member 6 are arranged on a planar base 2. However, as shown in FIG. 7, a transparent member 8 may be formed in a planar shape and a frame 7 may be provided between the base 2 and the transparent member 8. In such case, fourth pads 7b prepared on the frame 7 and third bumps provided on the transparent member 8 are coupled together, and the transparent member 8 is fixed to the base 2 through the frame 7. It is unnecessary to form the frame 7 with a transparent resin, since it is not needed to be transparent. Also, the frame 7 may be fixed to the base 2 with an adhesive or the like, or the frame 7 may be formed integrally with the base 2. According to such a modified example of optical module as described above, the shape of the transparent member 8 formed by injection molding can be simplified, which will result in improved yield of forming the transparent member 8.

### INDUSTRIAL APPLICABILITY

The optical module of the invention can be used for connection between signal processors such as LSIs or connection between a signal processor and an external interface such as a router or the like.

What is claimed is:

1. An optical module comprising
a base and
an opto-electric device having a first surface and a second surface lying opposite the first surface,
wherein an active layer is provided on the first surface, and first bumps or first pads are provided on the second surface, and wherein the opto-electric device is fixed to the base through the first bumps or the first pads.

2. An optical module according to claim 1,
wherein the first bumps or the first pads are formed of gold, and second pads or second bumps made of gold are provided on the base at positions corresponding to the first bumps or first pads, respectively.

3. An optical module according to claim 1, further comprising a transparent member covering the opto-electric device and fixed to the base, the transparent member having an optical part at a position facing the active layer of the opto-electric device,
wherein third bumps or third pads are provided at positions to contact the base so that the transparent member is fixed to the base through the third bumps or the third pads.

4. An optical module according to claim 3,
wherein the third bumps or the third pads are formed of gold, and fourth pads or fourth bumps made of gold are provided on the base at positions corresponding to the third bumps or the third pads, respectively.

5. An optical module according to claim 3,
wherein the third bumps or the third pads are made of a solder, and the transparent member is made of a thermoplastic resin that enables the transparent member to exhibit an average transmissivity of 60% or more at a thickness of 2 mm for a wavelength in the range of 600 to 1000 nm when the transparent member has been kept at 200° C. for 10 minutes.

6. An optical module according to claim 1, further comprising a control circuit for controlling the opto-electric device provided on the base,
wherein the control circuit and the opto-electric device are electrically connected by wire bonding.

7. A method of manufacturing an optical module, comprising the steps of:
forming first bumps or first pads on a second surface of an opto-electric device, the opto-electric device including a first surface having an active layer provided thereon, the second surface being opposite to the first surface; and
fixing the opto-electric device to a base through the first bumps or the first pads.

8. A method of manufacturing an optical module according to claim 7, further comprising:
a step of providing, on the base, a control circuit for controlling the opto-electric device; and
a step of electrically connecting the control circuit and the opto-electric device by wire bonding.

9. A method of manufacturing an optical module according to claim 7, further comprising:
a step of fixing a transparent member to the base such that an optical part provided thereon covers the opto-electric device,
wherein at the step of fixing the opto-electric device to the base, an alignment mark on the base is used for positioning the opto-electric device and the optical part, and at the step of fixing the transparent member to the base, the transparent member is arranged on the base by using the alignment mark such that the optical part is located at a position facing the active layer.
